(19) United States
(12) Patent Application Publication
(10) Pub. No.: US 2022/0050985 A1
(43) Pub. Date: Feb. 17, 2022

(54) BIOMETRIC SENSING APPARATUS

(71) Applicant: Au Optronics Corporation, Hsinchu (TW)

(72) Inventors: Chi-Cheng Chen, Hsinchu (TW); Gui-Wen Liu, Hsinchu (TW); Tsu-Chien Tung, Hsinchu (TW)

(73) Assignee: Au Optronics Corporation, Hsinchu (TW)

(21) Appl. No.: 17/356,483

(22) Filed: Jun. 23, 2021

Related U.S. Application Data
(60) Provisional application No. 63/066,405, filed on Aug. 17, 2020.

(30) Foreign Application Priority Data
Apr. 6, 2021 (TW) 110112391

(51) Int. Cl. G06K 9/00; H01L 27/146; G06F 3/044

(52) U.S. Cl. CPC G06K 9/0002; H01L 27/14678; G06F 3/0445; H01L 27/14627; H01L 27/14623

(57) ABSTRACT

A biometric sensing apparatus, including a light sensing device, a first light shielding layer, a second light shielding layer, and a capacitive sensing device, is provided. The light sensing device is disposed on a substrate. The first light shielding layer is disposed on the light sensing device. The first light shielding layer has a first pinhole corresponding to the light sensing device. The second light shielding layer is disposed on the first light shielding layer. The second light shielding layer has a second pinhole corresponding to the first pinhole. At least one of the first light shielding layer and the second light shielding layer is a first sensing electrode of the capacitive sensing device.

### CROSS-REFERENCE TO RELATED APPLICATION

This application claims the priority benefit of U.S. Provisional Application No. 63/066,405, filed on Aug. 17, 2020 and Taiwan application serial no. 110112391, filed on Apr. 6, 2021. The entirety of each of the above-mentioned patent applications is hereby incorporated by reference herein and made a part of this specification.

### BACKGROUND

### Technical Field

The disclosure relates to a sensing apparatus, and more particularly to a biometric sensing apparatus.

### Description of Related Art

The thickness of the conventional optical under display fingerprint module often has the issue of being too thick. In addition, how to improve the anti-counterfeiting identification ability of the optical under display fingerprint module is also a topic of current research.

### SUMMARY

The disclosure provides a biometric sensing apparatus, which can have a thinner thickness and/or better identification performance.

The biometric sensing apparatus of the disclosure includes a light sensing device, a first light shielding layer, a second light shielding layer, and a capacitive sensing device. The light sensing device is disposed on a substrate. The first light shielding layer is disposed on the light sensing device. The first light shielding layer has a first pinhole corresponding to the light sensing device. The second light shielding layer is disposed on the first light shielding layer. The second light shielding layer has a second pinhole corresponding to the first pinhole. At least one of the first light shielding layer and the second light shielding layer is a first sensing electrode of the capacitive sensing device.

Based on the above, by using at least one of the first light shielding layer and the second light shielding layer as the first sensing electrode of the capacitive sensing device, the thickness of the biometric sensing apparatus may be thinner. In addition, by integrating the light sensing device and the capacitive sensing device, the biometric sensing apparatus may have better identification performance (for example, the anti-counterfeiting identification ability of an optical under display fingerprint module may be improved, but not limited thereto).

### BRIEF DESCRIPTION OF THE DRAWINGS

FIG. 1A is a schematic cross-sectional view of a portion of a biometric sensing apparatus and a usage manner thereof according to a first embodiment of the disclosure.

FIG. 1B is a schematic cross-sectional view of a portion of the biometric sensing apparatus according to the first embodiment of the disclosure.

FIG. 1C is a schematic view of a portion of the circuit connection of the biometric sensing apparatus according to the first embodiment of the disclosure.

FIG. 1D is a schematic top view of a portion of the biometric sensing apparatus according to the first embodiment of the disclosure.

FIG. 1E is a timing view of a portion of the biometric sensing apparatus according to the first embodiment of the disclosure.

FIG. 2 is a schematic top view of a portion of a biometric sensing apparatus according to a second embodiment of the disclosure.

FIG. 3 is a schematic top view of a portion of a biometric sensing apparatus according to a third embodiment of the disclosure.

FIG. 4 is a schematic top view of a portion of a biometric sensing apparatus according to a fourth embodiment of the disclosure.

FIG. 5 is a schematic top view of a portion of a biometric sensing apparatus according to a fifth embodiment of the disclosure.

### DETAILED DESCRIPTION OF DISCLOSED EMBODIMENTS

For the features and advantages of the disclosure to be more obvious and understandable, the following specific embodiments are described in detail in conjunction with the accompanying drawings. Persons skilled in the art should understand that the described embodiments may be modified in various different ways without departing from the spirit or scope of the disclosure.

In the drawings, the thickness of each device, etc. is exaggerated for clarity. Throughout the specification, the same reference numerals represent the same devices. It should be understood that when a device such as a layer, a film, a region, or a substrate is referred to as “being on another device”, “being connected to another device”, or “overlapping with another device”, the device may be directly on the another device, connected to the another device, or there may be an intermediate device. In contrast, when a device is referred to as “being directly on another device” or “being directly connected to another device”, there is no intermediate device. As used herein, “connection” may refer to physical and/or electrical connection.

It should be understood that although terms such as “first”, “second”, and “third” may be used herein to describe various devices, components, regions, layers, and/or portions, the devices, components, regions, and/or portions are not limited by the terms. The terms are only used to distinguish one device, component, region, layer, or portion from another device, component, region, layer, or portion. Therefore, a “third device”, “component”, “region”, “layer”, or “portion” discussed below may be referred to as a second device, component, region, layer, or portion, and a “second device”, “component”, “region”, “layer”, or “portion” may be relatively referred to as a third device, component, region, layer, or portion without departing from the teachings herein.

The terminology used herein is only for the objective of describing specific embodiments and is not limiting. As used herein, unless the content clearly indicates otherwise, the singular forms “a”, “an”, and “the” are intended to include plural forms, including “at least one.” “Or” represents “and/or”. As used herein, the term “and/or” includes any and all combinations of one or more of the relevant listed items. It should also be understood that when used in the specification, the terms “including” and/or “comprising” designate the presence of the feature, region, entirety, step, operation, device, and/or component, but do not exclude the presence or addition of one or more other features, regions, entireties, steps, operations, devices, components, and/or combinations thereof.

In addition, relative terms such as “lower” and “upper” may be used herein to describe the relationship between a device and another device, as shown in the drawings. It should be understood that relative terms are intended to include different orientations of an apparatus in addition to the orientation shown in the drawings. For example, if the apparatus in a drawing is flipped, a device described as being on the “lower” side of other devices will be oriented on the “upper” side of the other devices. Therefore, the exemplary term “lower” may include the orientations of “lower” and “upper”, depending on the specific orientation of the drawing. Similarly, if the apparatus in a drawing is flipped, a device described as “below” or “beneath” other devices will be oriented “above” the other devices. Therefore, the exemplary terms “below” or “beneath” may include the orientations of above and below.

As used herein, “basically” or other similar terms include the stated value and an average value within an acceptable range of deviation from the specific value determined by persons skilled in the art while taking into account the measurement in question and the specific amount of measurement-related errors (that is, the limitation of the measurement system). For example, “ basically” may represent being within one or more standard deviations, ±30%, ±20%, ±10%, or ±5% of the stated value.

Unless otherwise defined, all terms (including technical and scientific terms) used herein have the same meaning as commonly understood by persons skilled in the art of the disclosure. It will be further understood that terms such as those defined in commonly used dictionaries should be interpreted as having meanings consistent with the meanings in the context of the art and the disclosure, and will not be interpreted as having idealized or overly formal meanings unless explicitly defined herein.

The exemplary embodiments are described herein with reference to cross-sectional views that are schematic diagrams of idealized embodiments. Therefore, changes in shapes of illustration as a result of, for example, manufacturing technology and/or tolerances may be expected. Therefore, the embodiments described herein should not be interpreted as being limited to the specific shapes of the regions as shown herein, but include, for example, shape deviations caused by manufacturing. For example, a region that is shown or described as flat may generally have a rough and/or non-linear feature. In addition, an acute angle shown may be rounded. Therefore, the regions shown in the drawings are schematic in nature, and the shapes thereof are not intended to show the precise shapes of the regions and are not intended to limit the scope of the claims.

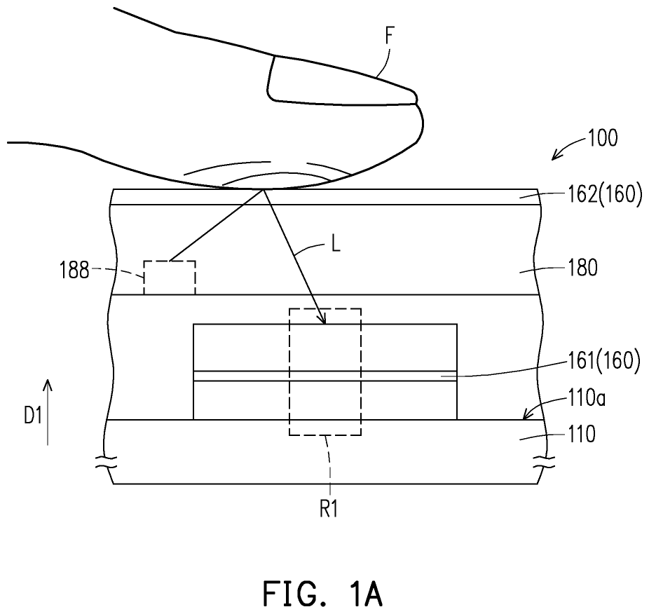

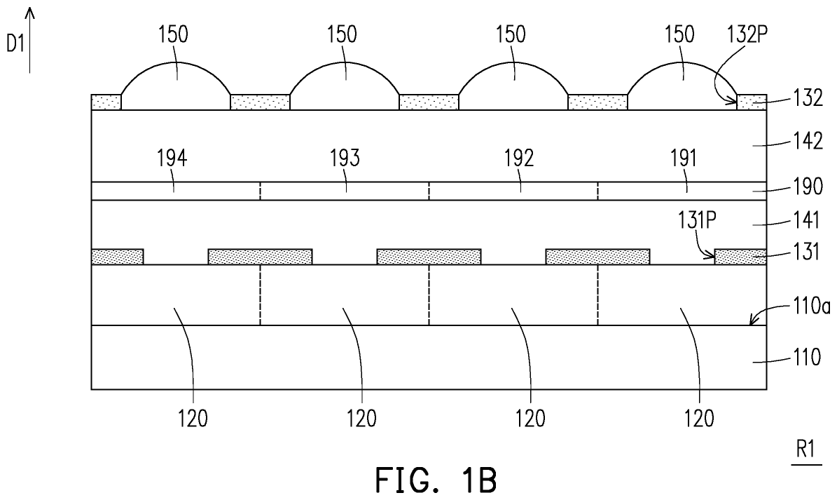

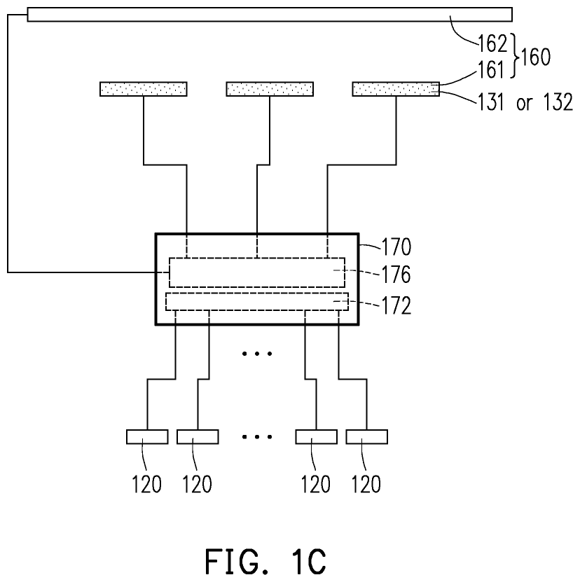

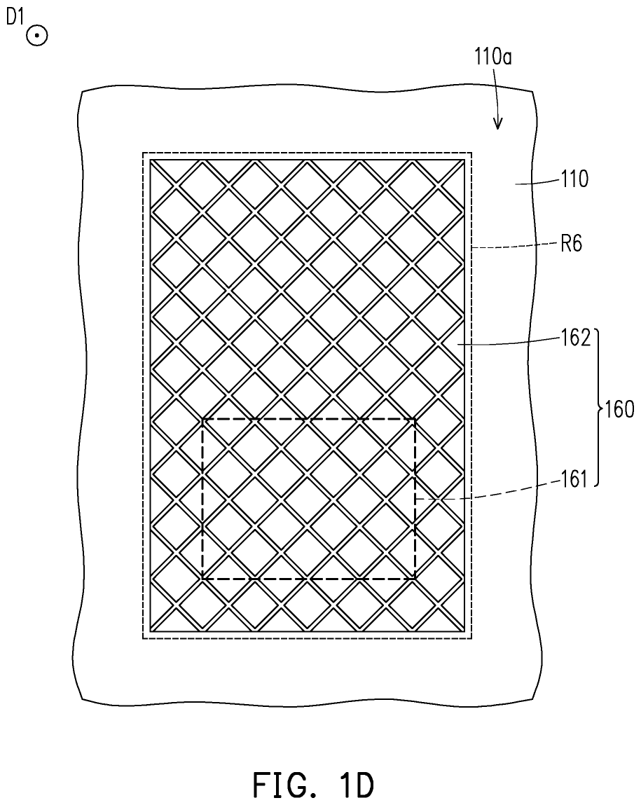

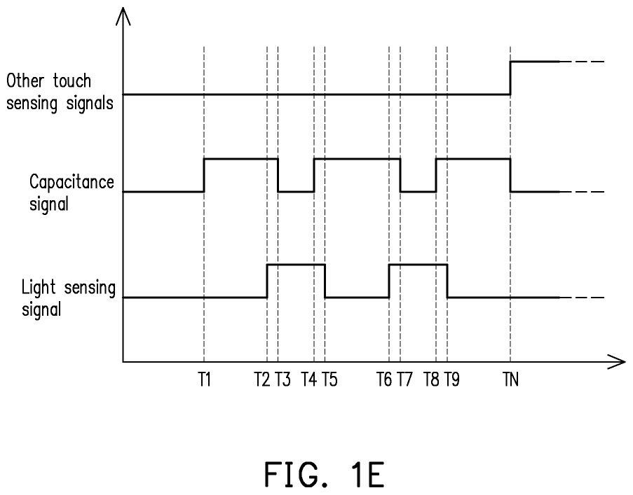

FIG. 1A is a schematic cross-sectional view of a portion of a biometric sensing apparatus and a usage manner thereof according to a first embodiment of the disclosure. FIG. 1B is a schematic cross-sectional view of a portion of the biometric sensing apparatus according to the first embodiment of the disclosure. FIG. 1C is a schematic view of a portion of the circuit connection of the biometric sensing apparatus according to the first embodiment of the disclosure. FIG. 1D is a schematic top view of a portion of the biometric sensing apparatus according to the first embodiment of the disclosure. FIG. 1E is a timing view of a portion of the biometric sensing apparatus according to the first embodiment of the disclosure. For example, in FIG. 1A or FIG. 1D, only a portion of the position or a portion of the region corresponding to a light sensing device or a capacitive sensing device in the biometric sensing apparatus is exemplarily shown. FIG. 1B may be an enlarged view corresponding to a region R1 in FIG. 1A.

A biometric sensing apparatus 100 includes a light sensing device 120, a first light shielding layer 131, a second light shielding layer 132, and a capacitive sensing device 160. The light sensing device 120 is disposed on a substrate surface 110a of a substrate 110. The first light shielding layer 131 is disposed on the light sensing device 120. The first light shielding layer 131 has a first pinhole 131P corresponding to the light sensing device 120. The second light shielding layer 132 is disposed on the first light shielding layer 131. The second light shielding layer 132 includes a second pinhole 132P corresponding to the first pinhole 131P. At least one of the first light shielding layer 131 and the second light shielding layer 132 is a first sensing electrode 161 of the capacitive sensing device 160. In other words, the first light shielding layer 131 or the second light shielding layer 132 as the first sensing electrode 161 is a conductive layer.

In this embodiment, the pinhole of the light shielding layer (for example, the first pinhole 131P of the first light shielding layer 131 and/or the second pinhole 132P of the second light shielding layer 132) may correspond to the light sensing device 120, but the disclosure is not limited thereto. In an embodiment that is not shown, multiple pinholes of the light shielding layer (such as multiple first pinholes 131P of the first light shielding layer 131 and/or multiple second pinholes 132P of the second light shielding layer 132) may correspond to a light sensitive device similar to the light sensing device 120.

In this embodiment, the biometric sensing apparatus 100 may further include an insulating layer. The insulating layer may be composed of multiple stacked insulating film layers. The overall insulating layer or a portion of the insulating layer may be referred to as a planarization (PL) layer, a protective layer (for example, a back channel passivation (BP) layer), or a buffer layer, but the disclosure is not limited thereto.

In this embodiment, the first light shielding layer 131 and the second light shielding layer 132 may be separated from each other by the insulating layer between each other. For example, the biometric sensing apparatus 100 may further include a first insulating layer 141 or a second insulating layer 142, but the disclosure is not limited thereto. The first insulating layer 141 may cover the first light shielding layer 131. The second light shielding layer 132 may cover the second insulating layer 142.

In an embodiment, a portion of the insulating layer may be filled with the corresponding pinhole in the light shielding layer, but the disclosure is not limited thereto. For example, a portion of the first insulating layer 141 may be filled with the first pinhole 131P of the first light shielding layer 131.

In this embodiment, the biometric sensing apparatus 100 may further include a light guiding device 150. The light guiding device 150 may correspond to the pinhole of the light shielding layer (for example, the second pinhole 132P of the second light shielding layer 132). The light guiding device 150 may include a lens (for example, a micro lens), but the disclosure is not limited thereto.

In an embodiment, the light guiding device 150 may be embedded in the pinhole of the corresponding light shielding layer, but the disclosure is not limited thereto.

In an embodiment, the light guiding device 150 may be a pre-formed device, but the disclosure is not limited thereto.

In an embodiment, the light guiding device 150 may be formed by embossing. For example, a transparent material may be coated on the top surface of the corresponding light shielding layer (for example, corresponding to the light sensing device 120, the surface among the light shielding layers farthest away from the light sensing device 120). Then, the corresponding light guiding device 150 is formed by embossing the transparent material.

In this embodiment, the biometric sensing apparatus 100 may further include a filter layer. The filter layer may be located on the light sensing device 120. The filter layer may include infrared-cut (IR-cut) material, IR filter material, red filter material, green filter material, blue filter material, or other possible color filter materials.

In an embodiment, the filter layer 190 may have different materials in different regions, but the disclosure is not limited thereto. For example, in the filter layer 190, two of a region 191, a region 192, a region 193, or a region 194 may have different materials.

In this embodiment, the filter layer 190 may be located between the first insulating layer 141 and the second insulating layer 142, but the disclosure is not limited thereto.

In an embodiment, the signal-to-noise ratio (SNR) of the corresponding light sensing device 120 may be increased by the filter layer 190.

In an embodiment, the light sensing device 120 may be composed of multiple stacked film layers (for example, a corresponding electrode layer and a corresponding photosensitive layer), but the disclosure is not limited thereto. The photosensitive layer may include a photoelectric conversion material. For example, the photosensitive layer may enable the light sensing device 120 to generate a corresponding electrical signal by absorbing light, but the disclosure is not limited thereto. In an embodiment, the material of the photosensitive layer may include silicon rich oxide (SRO), silicon rich nitride (SRN), silicon rich oxynitride (SRON), silicon rich carbide (SRC), silicon rich oxycarbide, hydrogenated silicon rich oxide, hydrogenated silicon rich nitride, hydrogenated silicon rich oxynitride, or a combination, doping, or stacking of the above, but the disclosure is not limited thereto.

In a possible embodiment, the light sensing device 120 may include a modular light sensing device.

In an embodiment, if (that is, one of the possible aspects) the conductive first light shielding layer 131 is the first sensing electrode 161 of the capacitive sensing device 160, the conductive first light shielding layer 131 is electrically separated from the light sensing device 120.

In an embodiment, if (that is, one of the possible aspects) the conductive second light shielding layer 132 is the first sensing electrode 161 of the capacitive sensing device 160, the conductive second light shielding layer 132 is electrically separated from the light sensing device 120.

In an embodiment, if (that is, one of the possible aspects) the conductive first light shielding layer 131 and the conductive second light shielding layer 132 are the first sensing electrode 161 of the capacitive sensing device 160, the conductive first light shielding layer 131 and the conductive second light shielding layer 132 are electrically separated from the light sensing device 120. In addition, the first light shielding layer 131 and the second light shielding layer 132 constituting the first sensing electrode 161 may be electrically connected to each other by other conductive devices (for example, conductive vias, but not limited thereto) in other regions not shown.

In an embodiment, the first sensing electrode 161 of the capacitive sensing device 160 may be floating ground or physical ground, but the disclosure is not limited thereto.

In an embodiment, the pattern or layout of the first sensing electrode 161 may be adjusted according to design requirements, which is not limited by the disclosure. For example, when the first sensing electrode 161 does not correspond to or overlap with the region of the light sensing device 120, the pattern or layout thereof may be adjusted according to corresponding requirements of the circuit.

In this embodiment, the capacitive sensing device 160 may further include a second sensing electrode 162. In a thickness direction D1 (that is, a direction perpendicular to the substrate surface 110a) of the biometric sensing apparatus 100, the second sensing electrode 162 is disposed corresponding to the first sensing electrode 161. In other words, in the thickness direction D1, the second sensing electrode 162 overlaps (including completely overlaps or partially overlaps) with the first sensing electrode 161.

In an embodiment, the biometric sensing apparatus 100 may further include a protective layer (not shown) located on the second sensing electrode 162.

In this embodiment, in a certain region (for example, similar to the region suitable for pressing/touching by a finger F together with sensing and/or identification in FIG. 1A, but not limited thereto) of the biometric sensing apparatus 100, in the thickness direction D1 of the biometric sensing apparatus 100, the second sensing electrode 162, the first sensing electrode 161, and the light sensing device 120 may overlap with one another.

In an embodiment, the material of the second sensing electrode 162 may include zinc oxide (ZnO), tin oxide (SnO), indium-zinc oxide (IZO), gallium-zinc oxide (GZO), zinc-tin oxide (ZTO), indium-tin oxide (ITO), or a combination, doping, or stacking of the above, but the disclosure is not limited thereto.

In an embodiment, the pattern or layout of the second sensing electrode 162 may be adjusted according to design requirements, which is not limited by the disclosure.

In an embodiment, the capacitive sensing device 160 may be electrically connected to a capacitive sensing circuit 176 to perform a mutual capacitance sensing mode, a self capacitance sensing mode, or other possible sensing modes.

For example, the capacitive sensing circuit 176 may include a Tx driving circuit and a Rx driving circuit. The Tx driving circuit may be electrically connected to the corresponding second sensing electrode 162, and the Rx driving circuit may be electrically connected to the corresponding first sensing electrode 161. In the mutual capacitance sensing mode, during a touch detection time interval, a touch scan signal may be applied to the second sensing electrode 162 by the Tx driving circuit, and the corresponding first sensing electrode 161 may be coupled to the touch scan signal and may be reads and/or sensed by the Rx driving circuit. Taking the finger pressing or touching the biometric sensing apparatus 100 as an example (for example, as shown in FIG. 1A), the corresponding second sensing electrode 162 may be deformed (for example, the distance between the second sensing electrode 162 and the first sensing electrode 161 may be reduced) to change the sensing capacitance between the corresponding second sensing electrode 162 and the corresponding first sensing electrode 161. The touch sensing manner of the capacitive sensing device 160 is only exemplary, which is not limited by the disclosure.

Under natural or unintentional conditions, since the thickness or strength of the finger (for example, the finger F in FIG. 1A, but not limited thereto) is often uneven and/or the degree or position of pressing/touching by the finger is difficult to be consistent, when the capacitive sensing device 160 is pressed/touched by the finger, there are basically obvious or detectable/judgeable signal differences in different regions (for example, the corresponding second sensing electrode 162, but not limited thereto). In this way, whether the finger is actually pressing/touching may be distinguished by the capacitive sensing device 160. However, the disclosure does not limit the distinguishing manner.

In an embodiment, a sensing range R6 of the capacitive sensing device 160 is greater than or basically equal to 3 millimeters (mm)×3 mm and less than or basically equal to 50 mm×50 mm. In this way, the distance between the first sensing electrode 161 and the second sensing electrode 162 may be adjusted, and/or the capacitive sensing device 160 may have better accuracy. It is worth noting that the representation manner of the sensing range R6 only represents the area of the capacitive sensing device 160 projected onto the substrate surface 110a, and the disclosure does not limit the shape of the sensing range R6. For example, the shape of the capacitive sensing device 160 projected onto the substrate surface 110a may be quadrilateral, quadrilateral-like (for example, a similar quadrilateral with at least one rounded corner), other similar polygons, polygon-like, or possible shapes containing curved edges (for example, a circle or an oval).

In an embodiment, the size or number of sensor units may be adjusted according to design requirements, which is not limited by the disclosure. In other words, within the sensing range R6, one or more light sensor units or one or more capacitive sensor units may be included.

In this embodiment, the biometric sensing apparatus 100 may further include a display device 180. The display device 180 may be disposed between the first sensing electrode 161 and the second sensing electrode 162.

In an embodiment, the biometric sensing apparatus 100 may be referred to as an under display fingerprint sensor, but the disclosure is not limited thereto.

The display device 180 may include a liquid crystal display device, an organic light emitting diode display device, a light emitting diode display device, or other suitable display devices, which is not limited by the disclosure. In addition, in FIG. 1A, the arrangement and size of the display device 180 are only schematically shown and are not limited by the disclosure.

For example, a light emitting unit 188 in the display device 180 may emit a corresponding ray L. After being reflected by the finger F, a portion of the ray may be directed toward the light guiding device 150 (if any). In addition, the ray at an appropriate angle may be directed toward the light sensing device 120.

The light emitting unit 188 is, for example, a light emitting diode or a corresponding pixel unit, which is not limited by the disclosure.

In this embodiment, the biometric sensing apparatus 100 may be suitable for sensing the ray at least by the light sensing device 120. In an embodiment, the biometric sensing apparatus 100 may be suitable for sensing the ray reflected by biometrics (for example, a fingerprint, but not limited thereto), but the disclosure is not limited thereto.

In this embodiment, by the arrangement of the capacitive sensing device 160 and the light sensing device 120 in the biometric sensing apparatus 100, whether a fingerprint pattern or signal captured by the light sensing device 120 may be actually pressed/touched by the finger may be distinguished. In addition, since the conductive light shielding layer with the pinhole may serve as the sensing electrode of the capacitive sensing device 160, the thickness of the biometric sensing apparatus 100 may be reduced.

In this embodiment, the light sensing device 120 and the capacitive sensing device 160 are signal-connected to the same sensing chip 170. The sensing chip 170 may include a corresponding integrated circuit. For example, the sensing chip 170 may include a corresponding capacitive sensing circuit 176, a light sensing circuit 172, and/or a timing control circuit (not shown). During a sensing period, the light sensing device 120 is suitable for being input with a light sensing signal by the light sensing circuit 172, and the capacitive sensing device 160 is suitable for being input with a capacitance signal by the capacitive sensing circuit 176.

In an embodiment, the number of channels of the chip connected to the capacitive sensing device 160 may be less than the number of channels of the chip connected to the light sensing device 120, but the disclosure is not limited thereto.

In this embodiment, the timing of the light sensing signal and the timing of the capacitance signal at least partially overlap. Taking FIG. 1E as an example, the capacitive sensing device 160 may be enabled between a time T1 and a time T3, between a time T4 and a time T7, and between a time T8 and a time TN to have corresponding capacitance signals. The light sensing device 120 may be enabled between a time T2 and a time T5 and between a time T6 and time a T9 to have corresponding capacitance signals. The timing of FIG. 1E is only an exemplary representation and is not limited by the disclosure.

In an embodiment, when distinguishing whether the finger is actually pressing/touching by the capacitive sensing device 160, the fingerprint pattern or signal may be distinguished by the light sensing device 120. Alternatively, when the fingerprint pattern or signal is distinguished by the light sensing device 120, whether the finger is actually pressing/touching may also be distinguished by the capacitive sensing device 160. In this way, the biometric sensing apparatus 100 may be suitable for anti-counterfeiting biometric sensing and identification.

In this embodiment, the sensing period (for example, the time T1 to the time TN in FIG. 1E, but not limited thereto) is less than or basically equal to 5 seconds. As such, the accuracy of anti-counterfeiting identification may be improved (for example, the difficulty of simulated pressing and short-time pattern swapping may be improved).

In this embodiment, the length of the enabling time (enabling time) of the capacitance signal is greater than the length of the enabling time of the light sensing signal. In an embodiment, the sensing time and/or the reaction time of the light sensing signal is generally shorter than the sensing time and/or the reaction time of the capacitance signal. For example, the amount of deformation or capacitance change that can cause the capacitance signal to be generated may correspond to the reaction or the action time of an organism, so that a longer sensing time and/or reaction time is required. Therefore, the length of the enabling time of the capacitance signal may be greater than the length of the enabling time of the light sensing signal to improve the accuracy of identification.

In an embodiment, after completing biometric sensing and identification (for example, after the time TN), other touch sensing signals may be enabled to perform other touch sensing functions. For example, the light sensing signal and the capacitance signal may be used for the fingerprint unlocking function of the under display fingerprint sensor, and other touch sensing signals after completing fingerprint unlocking may be used for other applications.

It is worth noting that FIG. 1E is only an exemplary illustration, and the disclosure does not limit the number of enabling times of the light sensing signal and/or the capacitance signal.

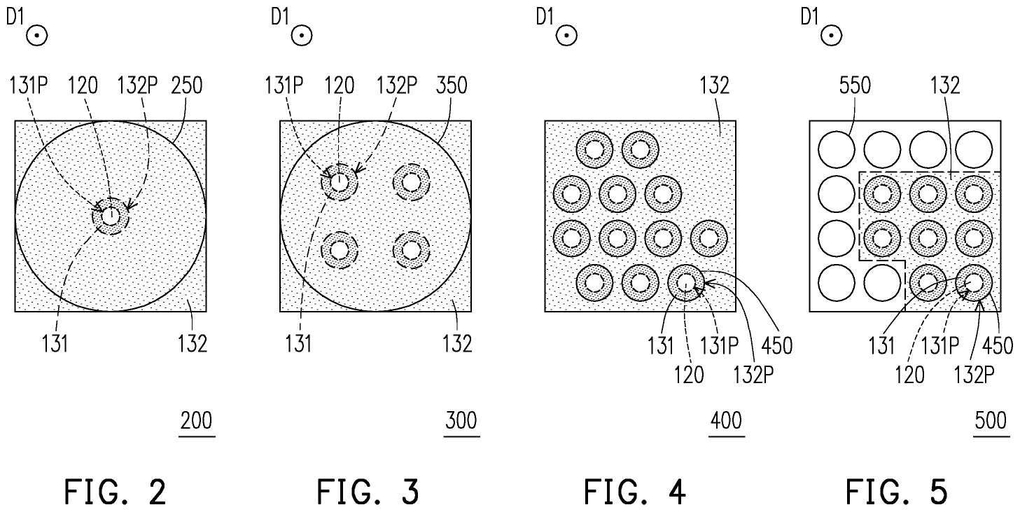

FIG. 2 is a schematic top view of a portion of a biometric sensing apparatus according to a second embodiment of the disclosure. A biometric sensing apparatus 200 of the second embodiment is similar to the biometric sensing apparatus 100 of the first embodiment, and similar parts are represented by the same reference numerals and have similar functions, materials, or formation manners, so the descriptions are omitted.

The biometric sensing apparatus 200 may include a light sensing device 120, a first light shielding layer 131, a second light shielding layer 132, a capacitive sensing device (not shown directly, but may be similar to the capacitive sensing device 160 of the foregoing embodiment), and a light guiding device 250.

In this embodiment, in a sensor unit, the light guiding device 250 may correspond to a pinhole of a light shielding layer (for example, a first pinhole 131P of the first light shielding layer 131 and a second pinhole 132P of the second light shielding layer 132).

FIG. 3 is a schematic top view of a portion of a biometric sensing apparatus according to a third embodiment of the disclosure. A biometric sensing apparatus 300 of the third embodiment is similar to the biometric sensing apparatus 100 of the first embodiment, and similar parts are represented by the same reference numerals and have similar functions, materials, or formation manners, so the descriptions are omitted.

The biometric sensing apparatus 300 may include a light sensing device 120, a first light shielding layer 131, a second light shielding layer 132, a capacitive sensing device (not shown directly, but may be similar to the capacitive sensing device 160 of the foregoing embodiment), and a light guiding device 350.

In this embodiment, in a sensor unit, the light guiding device 350 may correspond to multiple pinholes of a light shielding layer (for example, multiple first pinholes 131P of the first light shielding layer 131 and multiple second pinholes 132P of the second light shielding layer 132).

FIG. 4 is a schematic top view of a portion of a biometric sensing apparatus according to a fourth embodiment of the disclosure. A biometric sensing apparatus 400 of the fourth embodiment is similar to the biometric sensing apparatus 100 of the first embodiment, and similar parts are represented by the same reference numerals and have similar functions, materials, or formation manners, so the descriptions are omitted.

The biometric sensing apparatus 400 may include a light sensing device 120, a first light shielding layer 131, a second light shielding layer 132, a capacitive sensing device (not shown directly, but may be similar to the capacitive sensing device 160 of the foregoing embodiment), and a light guiding device 450.

In this embodiment, multiple light guiding devices 450 may be included in the sensor unit. In the sensor unit, each of the light guiding devices 450 may correspond to multiple pinholes of a light shielding layer (for example, multiple first pinholes 131P of the first light shielding layer 131 and multiple second pinholes 132P of the second light shielding layer 132).

In addition, for clarity, not all the light guiding devices 450, the first pinholes 131P, and the second pinholes 132P are labeled one by one in FIG. 4.

FIG. 5 is a schematic top view of a portion of a biometric sensing apparatus according to a fifth embodiment of the disclosure. A biometric sensing apparatus 500 of the fifth embodiment is similar to the biometric sensing apparatus 400 of the fourth embodiment, and similar parts are represented by the same reference numerals and have similar functions, materials, or formation manners, so the descriptions are omitted.

The biometric sensing apparatus 500 may include a light sensing device 120, a first light shielding layer 131, a second light shielding layer 132, a capacitive sensing device (not shown directly, but may be similar to the capacitive sensing device 160 of the foregoing embodiment), a light guiding device 450, and a dummy light guiding device 550. In this embodiment, the appearance, form, and/or size of the dummy light guiding device 550 may be the same or similar to the light guiding device 450. However, the ray basically cannot be directed toward the sensing device by the dummy light guiding device 550.

In an embodiment, the material of the dummy light guiding device 550 may be the same or similar to the light guiding device 450. The difference is that in a thickness direction D1, the light sensing device 120 does not overlap with the dummy light guiding device 550 and/or at least one light shielding layer between the light sensing device 120 and the dummy light guiding device 550 does not have pinholes corresponding to or overlapping with the dummy light guiding device 550.

In an embodiment, the material of the dummy light guiding device 550 may be different from the light guiding device 450. For example, the dummy light guiding device 550 may not be transparent.

In addition, for clarity, not all the light guiding devices 450, the first pinholes 131P, the second pinholes 132P, and the dummy light guiding devices 550 are labeled one by one in FIG. 5.

In the foregoing embodiments, the film layer may be a single-layer structure or a multi-layer structure. However, if the film layer is a stack of multi-layer structures, the multi-layer structures may not have materials with other properties therebetween. For example, the conductive layer may be a single-layer structure or a multi-layer structure. If the conductive layer is a multi-layer structure, the multi-layer structures may not have an insulating material therebetween. For another example, the insulating layer may be a single-layer structure or a multi-layer structure. If the insulating layer is a multi-layer structure, the multi-layer structures may not have conductive materials therebetween. For another example, the light shielding layer may be a single-layer structure or a multi-layer structure. If the light shielding layer is a multi-layer structure, the multi-layer structures may not have a transparent material therebetween.

In summary, in the disclosure, by using at least one of the first light shielding layer and the second light shielding layer as the first sensing electrode of the capacitive sensing device, the thickness of the biometric sensing apparatus may be thinner. In addition, by integrating the light sensing device and the capacitive sensing device, the biometric sensing apparatus may have better identification performance (for example, the anti-counterfeiting identification ability of an optical under display fingerprint module may be improved, but not limited thereto).

What is claimed is:

1. A biometric sensing apparatus, comprising:
a light sensing device, disposed on a substrate;
a first light shielding layer, disposed on the light sensing device and having a first pinhole corresponding to the light sensing device;
a second light shielding layer, disposed on the first light shielding layer and having a second pinhole corresponding to the first pinhole; and
a capacitive sensing device, wherein at least one of the first light shielding layer and the second light shielding layer is a first sensing electrode of the capacitive sensing device.

2. The biometric sensing apparatus according to claim 1, wherein the first light shielding layer is electrically separated from the light sensing device, and/or the second light shielding layer is electrically separated from the light sensing device.

3. The biometric sensing apparatus according to claim 1, wherein the first light shielding layer and the second light shielding layer are the first sensing electrode of the capacitive sensing device.

4. The biometric sensing apparatus according to claim 1, wherein the capacitive sensing device further comprises a second sensing electrode disposed corresponding to the first sensing electrode in a thickness direction of the biometric sensing apparatus.

5. The biometric sensing apparatus according to claim 4, wherein a sensing range of the capacitive sensing device is greater than or equal to 3 mm×3 mm and less than or equal to 50 mm×50 mm.

6. The biometric sensing apparatus according to claim 4, further comprising:
a display device, disposed between the first sensing electrode and the second sensing electrode.

7. The biometric sensing apparatus according to claim 1, wherein the light sensing device and the capacitive sensing device are signal-connected to a same sensing chip.

8. The biometric sensing apparatus according to claim 1, wherein during a sensing period, the light sensing device is input with a light sensing signal, the capacitive sensing device is input with a capacitance signal, and a timing of the light sensing signal and a timing of the capacitance signal at least partially overlap.

9. The biometric sensing apparatus according to claim 1, wherein during a sensing period, the light sensing device is input with a light sensing signal, the capacitive sensing device is input with a capacitance signal, and the sensing period is less than or equal to 5 seconds.

10. The biometric sensing apparatus according to claim 1, wherein during a sensing period, the light sensing device is input with a light sensing signal, the capacitive sensing device is input with a capacitance signal, and an enabling time length of the capacitance signal is longer than an enabling time length of the light sensing signal.
